(19) United States
(12) Patent Application Publication
(10) Pub. No.: US 2025/0097609 A1
(43) Pub. Date: Mar. 20, 2025

(54) WIFI ACCESS POINT ENCLOSURE

(71) Applicant: Hubbell Incorporated, Shelton, CT (US)

(72) Inventors: Rodolfo Pepper Valdez, JR., San Antonio, TX (US); Connor Burke, San Antonio, TX (US); Rich Hummel, Bandera, TX (US)

(21) Appl. No.: 18/887,719

(22) Filed: Sep. 17, 2024

Related U.S. Application Data
(60) Provisional application No. 63/583,441, filed on Sep. 18, 2023.

(51) Int. Cl. H04Q 1/02; H05K 7/14

(52) U.S. Cl. CPC H04Q 1/11; H04Q 1/023; H05K 7/14

(57) ABSTRACT

An enclosure for a network device includes a housing defining an interior for receiving a network device. A slide bracket is positioned in the housing. A tray is configured to receive the network device and is slideably connected to the slide bracket and moveable between an open position and a closed position. The base is pivoted inside of the housing as the tray is moved to the closed position to an operation position.

### RELATED APPLICATION(S)

This application claims priority to U.S. Provisional Application No. 63/583,441, filed Sep. 18, 2023, the disclosure of which is hereby incorporated by reference in its entirety.

### FIELD

Various exemplary embodiments relate to enclosures for network devices used in high density WiFi systems.

### BACKGROUND

Use of high density WiFi in venues such as stadiums and arenas has grown rapidly, and the need to provide adequate coverage has become essential for venue operators. Early networks used overhead antennas mounted throughout the venues. However, complete coverage was difficult with this architecture due to the distance between the antennas and most users, especially those in the lower or front sections. This architecture also required each antenna to serve a large number of people, which could easily overload the network.

To alleviate these issues, access points have been added in the occupied areas of the venue, for example around hand rails and under seats. These access points can be spread out through the venue to create smaller usage cells to increase the network capacity and provide near uniform coverage to users.

### SUMMARY

In certain configurations, an enclosure for a network device includes a slidable tray to slidably position the network device in the enclosure.

In certain configurations, an enclosure for a network device is configured to orient the network device at an angle.

In certain configurations, an enclosure for a network device includes a housing defining an interior for receiving a network device. A slide bracket is positioned in the housing. A tray is configured to receive the network device and is slideably connected to the slide bracket and moveable between an open position and a closed position. The base is pivoted inside of the housing as the tray is moved to the closed position to an operation position.

In certain configurations, an enclosure for a network device includes a housing defining an interior for receiving a network device. A slide bracket is positioned in the housing. A tray includes a front body portion and a base pivotally connected to the front body portion. The base is configured to receive the network device. The tray slideably connected to the slide bracket and moveable between an open position and an operation position.

In certain configurations, an enclosure for a network device includes a housing defining an interior for receiving a network device. A faceplate is connected to the housing. A slide bracket is positioned in the housing. A tray includes a base configured to receive the network device. The tray is slideably connected to the slide bracket and moveable between an open position and an operation position. A cover is connected to the tray. The base is pivoted inside of the housing as the tray is moved to the operation position to orient the base at an oblique angle.

### BRIEF DESCRIPTION OF THE DRAWINGS

The aspects and features of various exemplary embodiments will be more apparent from the description of those exemplary embodiments taken with reference to the accompanying drawings.

FIG. 1 is a front perspective view of an enclosure with a cover and tray removed from a housing.

FIG. 2 is a rear perspective view of the enclosure with the cover and tray in a closed position.

FIG. 3 is a front perspective, exploded view of the housing.

FIG. 4 is a front perspective, partially exploded view of the faceplate and slide bracket.

FIG. 5 is a rear perspective, partially exploded view of the faceplate and slide bracket.

FIG. 6 is a rear perspective view of the cover and tray.

FIG. 7 is a front perspective view of an enclosure with a cover and tray removed from a housing and a network device connected to the tray.

FIG. 8 is a front perspective view of the enclosure with the cover and tray in a closed position and a network device connected to the tray.

FIG. 9 is a side view of the enclosure with the cover and tray in a closed position and a network device connected to the tray.

FIG. 10 is a sectional view of FIG. 9.

FIG. 11 is a side, schematic view of the enclosure installed under a seat in a venue.

### DETAILED DESCRIPTION OF EXEMPLARY CONFIGURATIONS

Various exemplary embodiments are directed to enclosures for network devices used in WiFi systems. One type of network device includes WiFi access points (APs). APs enable wireless connectivity in diverse settings, ranging from personal spaces to large-scale public venues, industrial operations, and even remote locations. APs are used frequently in outdoor areas to provide WiFi access to public spaces, transportation hubs, and restaurants.

Such systems are often used in venues holding large numbers of people, such as indoor and outdoor concert venues, festivals, stadiums, and arenas. APs play a pivotal role in venues, offering advantages that enhance the overall experience for both attendees and venue operators. APs are strategically placed throughout the venue to provide wireless connectivity, allowing visitors to stay connected to the internet and access various services. APs enable spectators to share their experiences in real-time through social media, enhancing engagement and promoting the venue. Moreover, APs support mobile ticketing and vendor payment systems, reducing queues and enhancing convenience for attendees. For venue operators, APs can offer valuable data insights into attendee behavior and preferences, enabling targeted marketing and operational improvements. Additionally, APs can help facilitate communications, security, and emergency services, ensuring the safety and well-being of all those within the venue.

In most locations, it is desirable to use enclosures or housings for APs to protect them from environmental factors, enhance security, optimize antenna performance, and ensure they meet the specific needs of different environments. The choice of housing depends on the AP's deployment location and the unique challenges posed by that setting.

Housings provide physical protection for APs against environmental factors such as dust, moisture, extreme temperatures, and physical damage. This can be especially important in outdoor or industrial settings where APs need to be shielded from harsh conditions and debris. It can also be necessary to provide watertight or water resistant enclosures that can allow for pressure washing around the device. Enclosures can also be lockable or tamper-resistant, preventing unauthorized access to the APs or their configuration. This can be important in public areas or high-security environments where physical security is a concern.

In some settings, APs need to blend seamlessly with the architecture or interior design. Housings can be designed to match the aesthetics of their surroundings, making them less obtrusive. Housings can come with various mounting options, allowing for secure attachment to walls, poles, ceilings, or other structures, depending on the installation requirements.

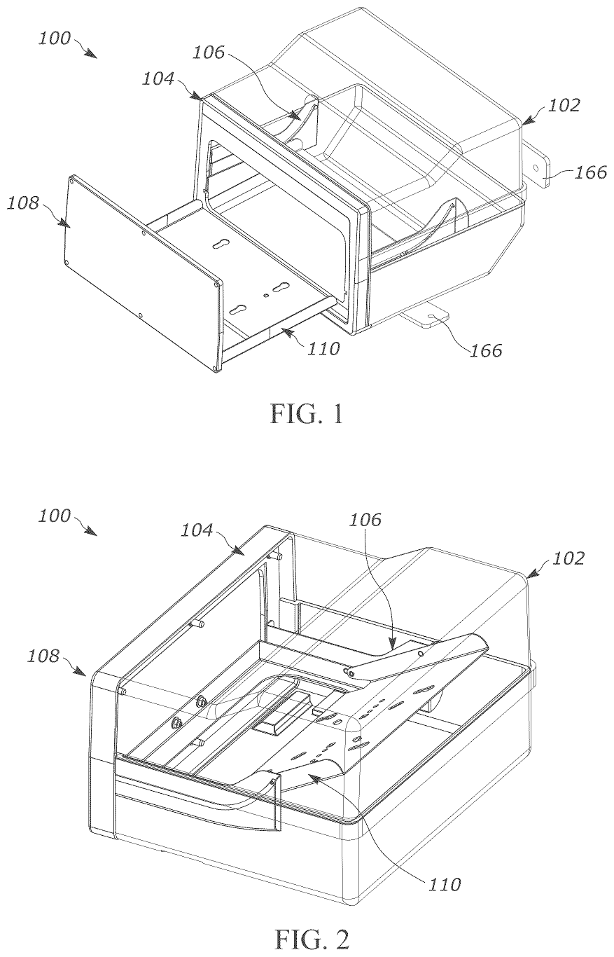

FIGS. 1 and 2 show an exemplary embodiment of an enclosure 100 for a network device, for example a WiFi access point. The enclosure 100 includes a housing 102, a faceplate 104 connected to the housing 102, a slide bracket 106 positioned in the housing 102, and a cover 108 and a tray 110 slidably connected to the housing 102. The housing 102 defines an interior for receiving a network device, such as wireless access point. The cover 108 and tray 110 can be moved from a closed position which places the network device inside of the housing 102 to an open position which allows physical access to the network device.

The housing 102 is configured to be placed in an environment such as a sporting or concert venue. In certain implementation, the housing 102 is configured to be placed under a seat in the venue. The housing 102 can be impact resistant and water resistant to protect against weather, debris ingress, and allow for pressure washing.

In certain configurations, the housing 102 includes an upper housing body 112 and a lower housing body 114 that at least partially define an interior and a front opening. The upper housing body 112 and the lower housing body 114 can be formed as separate pieces that are connected together. This can allow for different size and shape components to be used as needed, dependent on the requirements of the location.

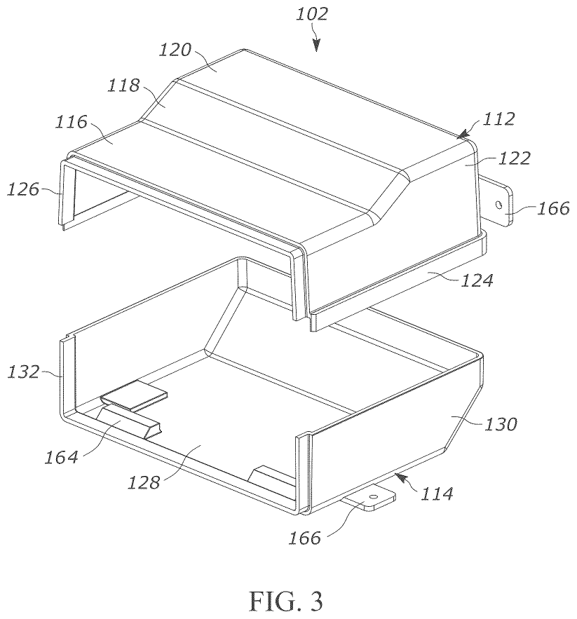

As best shown in FIG. 3, the upper housing body 112 can have an upper portion with a front section 116, a middle section 118, and a rear section 120. The middle section 118 can be angled relative to the front section 116 to provide a stepped configuration. One or more side walls 122 can extend from the upper portion. An outer flange 124 can extend from the one or more side walls 122. An upper front flange 126 can extend from one or more of the front section 116 And upper side walls 122 to define an upper forward rim.

The lower housing body 114 can include a bottom wall 128 and one or more lower side walls 130 extending from the bottom wall 128. The lower side walls 130 can include an upper edge that fits within the outer flange 124. A lower front flange 132 can extend from the lower side walls 130 to define a lower forward rim.

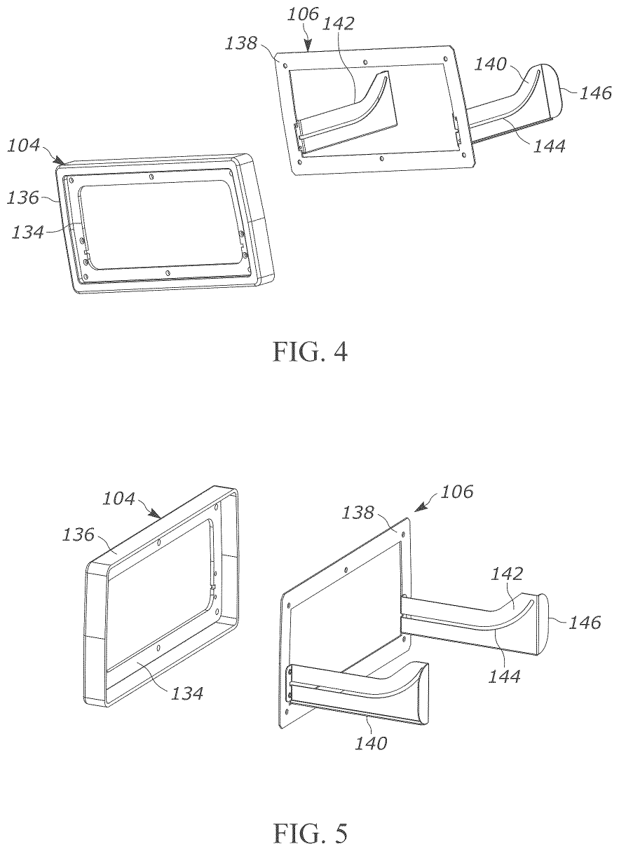

FIGS. 4 and 5 show an exemplary configuration of the faceplate 104 and the slide bracket 106. The faceplate 104 includes an inner wall 134 and an outer wall 136 extending from the inner wall 134. A plurality of openings are provided in the inner wall 134. The outer wall 136 can extend in front of and behind the inner wall 134 to define a front recess and a rear recess. The rear recess can receive the upper and lower forward flange 126, 132 of the housing 102 to position the faceplate 106 on the upper and lower forward rim.

The slide bracket 106 can include a fastener plate 138. The fastener plate 138 has a series of openings that align with openings on the faceplate 106. The faceplate 106 can be secured to the fastener plate 138 using one or more mechanical fasteners. For example, rivets can extend through the faceplate 106 to secure to the fastener plate 138.

A first arm 140 and a second arm 142 are connected to the fastener plate 138. The first and second arms 140, 142 can be secured to the fastener plate 138 using mechanical fasteners or connected by welding. Each of the arms 140, 142 include a slot 144 that forms a track to slidably receive at least a portion of the tray 110. The slots 144 can include a first section proximate the opening and a second section extending from the first section to the rear of the housing. The second section can have at least a portion which extends at an oblique angle to the first portion. For example, the second section can include a curved portion that curves up toward the top of the housing 102 to define an operation angle for the tray 110 when the cover 108 is in the closed position.

In an exemplary embodiment, the operation angle can be approximately 30 degrees. In other configurations, the angle can be between 0 and 90 degrees. The operational angle can be measured relative to a surface attachment and can be dependent on the placement of the housing 102.

A tab 146 can extend from each of the first arm and the second arm outwardly to the side walls of the housing. The tab 146 can help position the arms in the housing 102 and space them from the side walls 122, 130.

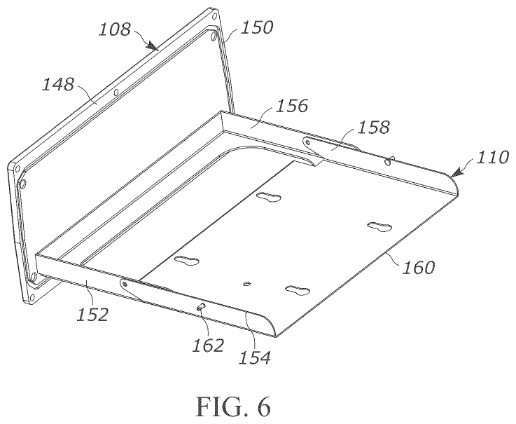

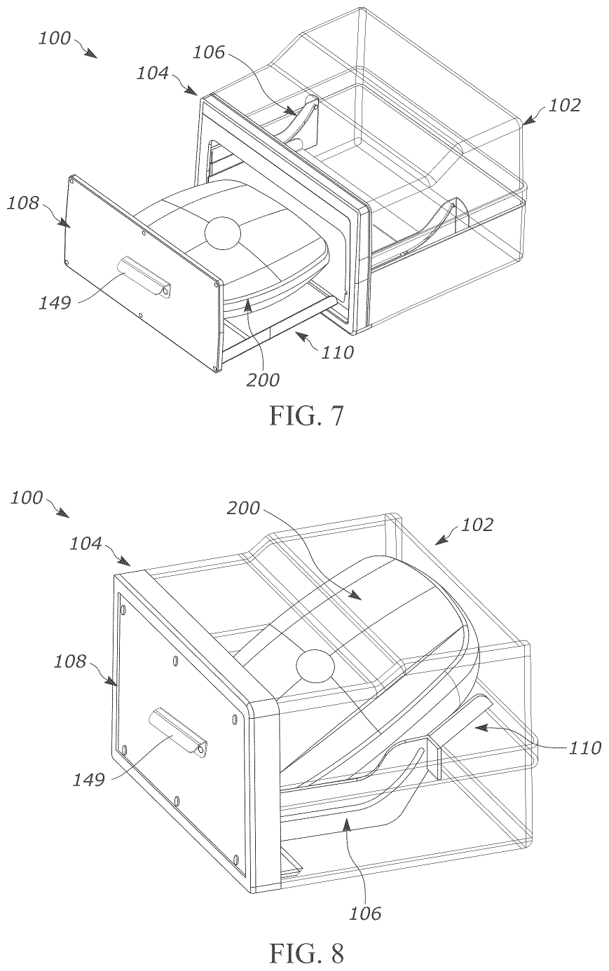

FIG. 6 shows an exemplary embodiment of the cover 108 and the tray 110. The cover 108 includes a front wall 148. The front wall 148 can include a handle 149 (shown in FIGS. 7 and 8). A plurality of openings can extend through the front wall 148. The openings can receive fasteners to secure the cover 108 to the faceplate 106 in a closed position. In certain configurations, the fasteners can be tamper-resistant or anti-vandal fasteners that would help limit unwanted access to the housing 102. Other configurations can utilize a locking mechanism to secure the housing. A channel 150 can be formed on the interior of the cover 108 to receive a gasket.

The tray 110 is connected to the cover 108 and includes a front body portion 152 and a rear body portion 154. The front body portion 152 includes one or more front side walls 156. The rear body portion 154 includes one or more rear side walls 158 and a base 160 extending between the rear side walls 158. The base 160 can include a plurality of openings. In certain configurations, the openings can include multiple sets of openings configured to secure a network device to the base 160. The different openings can be configured to accommodate different types of devices. In certain configurations the openings can optionally include a set of keyhole openings. In certain configurations the openings can optionally include a set of angled oval or obround openings. In certain configurations the openings can optionally include a set of apertures positioned along a line to adjust the horizontal positioning of the device.

The rear body portion 154 is pivotally connected to one or more of the front side walls 156. For example, a pivot pin can connect the front and rear body portions 152, 154 so that the rear body portion can rotate relative to the front body portion. A track pin 162 can extend from each of the rear side walls 158. The track pin 162 can be received in the slot 144 in the respective slide bracket arm 140, 142.

In certain configurations the operation angle can be measured on the angle of the rear body portion 154 relative to the front body portion 152. The operation angle can also be measured relative to the bottom wall 128 of the housing 102. In certain configurations the operation angle can be measured relative to a support surface to which the housing 102 is connected.

FIG. 7 shows a network device 200 connected to the tray 110. The cover 108 and tray 110 are in the open position with the tray 110 removed from the housing 102. In this position, the base 160 can lay substantially parallel to the bottom wall 128 of the housing 102. The slot 144 is aligned with an aperture in the fastener plate 138 and/or faceplate 104 so that the cover 108 and tray 110 can be completely removed from the housing 102 without having to dissemble any other portions of the housing 102. As the cover 108 and track 110 are inserted into the housing 102, the track pin 162 is placed in the slot 144 and moved from the open position to the closed position. Upon further closing, the track pin 162 enters the second section of the slot 144 and begins to pivot the second body portion 154 relative to the first body portion 152.

In certain implementations, one or more projections 164 can extend from the bottom wall 128 of the lower housing body 114 into the interior of the housing 102. In certain configurations, the projections 164 can have a trapezoidal configuration with an angled front wall facing the opening. Other shapes may also be used. The projections 164 can include matching depressions on the outer surface of the lower housing body 114.

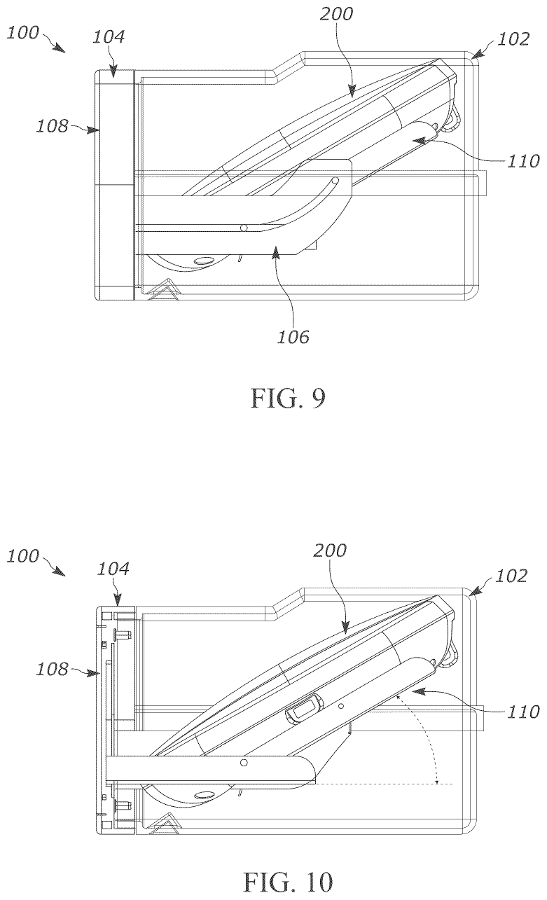

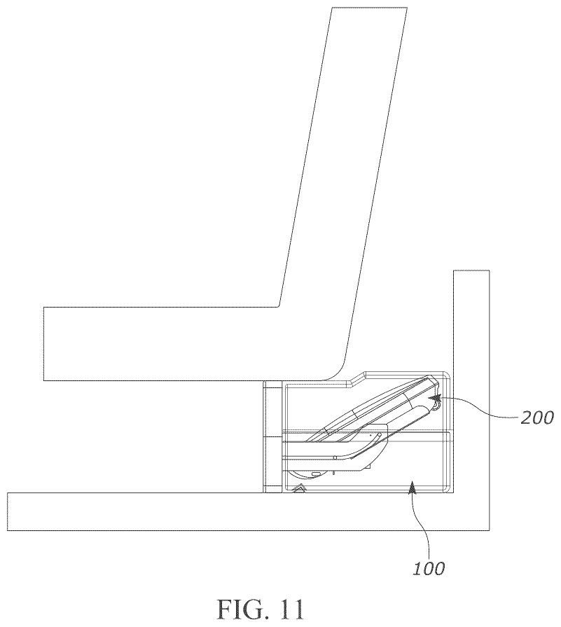

FIGS. 8-10 show the cover 108 and tray 110 in the closed position. The network device 200 is positioned entirely in the housing 102 and the second body portion 154 is rotated to the operation angle.

In certain implementations one or more brackets 166 can be connected to the housing 102. In certain configurations, the brackets 166 can be positioned in recesses formed in the upper housing body 112 and lower housing body 114 or connected to a flush surface. The brackets 166 can be connected using fasteners, such as bolts, rivets, or screws, or through a joining process such as welding. In other configurations, the brackets 166 can be connected to the housing 102 through a molding process.

The brackets 166 can have an outer portion that extends outside of the housing 102. The outer portion can include an opening for receiving a fastener. The fastener can be used to secure the housing 102 to a support surface in an external environment.

FIG. 11 shows the enclosure 100 positioned on a floor under a seat in a venue such as a stadium. The enclosure 100 can be mounted with various brackets, fasteners, or other mounting hardware or components. As shown, the stepped portion of the housing 102 gives more clearance for the network device 200 while also allowing the cover 108 to fit under the seat. This can allow removal of the cover 108 and tray 110 and access to the network device 200 without having to remove or dissemble any components of the enclosure 100 or the surrounding seat. As also shown, the operation angle allows for the network device 200 to be oriented so that an antenna is not blocked by the seat or the user. This helps provide better service and coverage to the venue.

Many network devices, such as APs, have antennas that need to be positioned optimally for signal coverage. The enclosure 100 can therefore be modified to ensure the best wireless performance. For example, the configuration of the slot 144 can be modified to adjust the operation position. For example the length, curve, angle, and final orientation of the slot 144 can be modified as needed based on the structure of the surrounding environment. Other manual adjustment devices can also be incorporated to allow for tuning of the operation angle. For example, set screws, jack screws, and/or other manual adjustment mechanisms can be provided to adjust the position of the base, the network device, or the arms/slots as needed.

The foregoing detailed description of the certain exemplary embodiments has been provided for the purpose of explaining the general principles and practical application, thereby enabling others skilled in the art to understand the disclosure for various embodiments and with various modifications as are suited to the particular use contemplated. This description is not necessarily intended to be exhaustive or to limit the disclosure to the exemplary embodiments disclosed. Any of the embodiments and/or elements disclosed herein may be combined with one another to form various additional embodiments not specifically disclosed. Accordingly, additional embodiments are possible and are intended to be encompassed within this specification and the scope of the appended claims. The specification describes specific examples to accomplish a more general goal that may be accomplished in another way.

As used in this application, the terms “front,” “rear,” “upper,” “lower,” “upwardly,” “downwardly,” and other orientational descriptors are intended to facilitate the description of the exemplary embodiments of the present disclosure, and are not intended to limit the structure of the exemplary embodiments of the present disclosure to any particular position or orientation. Terms of degree, such as “substantially” or “approximately” are understood by those of ordinary skill to refer to reasonable ranges outside of the given value, for example, general tolerances associated with manufacturing, assembly, and use of the described embodiments. Unless specified or limited otherwise, the terms “mounted,” “connected,” “supported,” and “coupled” and variations thereof are used broadly and encompass both direct and indirect mountings, connections, supports, and couplings.

What is claimed:

1. An enclosure for a network device comprising:
a housing defining an interior for receiving a network device;
a slide bracket positioned in the housing;
a tray configured to receive the network device is slideably connected to the slide bracket and moveable between an open position and an operation position; and
a cover connected to the tray,
wherein at least a portion of the tray is pivoted inside of the housing as the tray is moved to the operation position.

2. The enclosure of claim 1, wherein the slide bracket includes a slot.

3. The enclosure of claim 2, wherein the slot has a curved portion that causes rotation of the tray to the operation position.

4. The enclosure of claim 1, wherein the operation position orients the network device at an oblique angle relative to a horizontal plane of the housing.

5. The enclosure of claim 4, wherein the angle is between approximately 0 and 90 degrees.

6. The enclosure of claim 5, wherein the angle is approximately 30 degrees.

7. An enclosure for a network device comprising:
a housing defining an interior for receiving a network device;
a slide bracket positioned in the housing;
a tray having a front body portion and a base pivotally connected to the front body portion, the base configured to receive the network device, the tray slideably connected to the slide bracket and moveable between an open position and an operation position.

8. The enclosure of claim 7, wherein the base is pivotally connected to the front body portion by a pin.

9. The enclosure of claim 7, wherein the housing includes an upper body portion and a lower body portion.

10. The enclosure of claim 7, wherein a bracket is connected to the housing for securing the housing to a support.

11. The enclosure of claim 7, wherein the housing includes a front opening and a removable cover is configured to be positioned over the front opening.

12. The enclosure of claim 7, wherein the base includes a set of keyhole apertures for receiving fastener to secure the network device to the base.

13. The enclosure of claim 7, wherein the slide bracket includes a curved slot.

14. The enclosure of claim 13, wherein the base includes a pin configured to slidably engage the curved slot.

15. An enclosure for a network device comprising:
a housing defining an interior for receiving a network device;
a faceplate connected to the housing;
a slide bracket positioned in the housing;
a tray having a base, the base configured to receive the network device, the tray slideably connected to the slide bracket and moveable between an open position and an operation position; and
a cover connected to the tray,
wherein the base is pivoted inside of the housing as the tray is moved to the operation position to orient the base at an oblique angle.

16. The enclosure of claim 15, wherein the housing includes an upper body portion and a lower body portion.

17. The enclosure of claim 15, wherein housing includes a forward flange for receiving the faceplate.

18. The enclosure of claim 15, wherein the housing includes a projection extending from a bottom wall into the interior.

19. The enclosure of claim 15, wherein the slide bracket includes a fastener plate and the cover includes an opening for receiving a fastener to secure the cover to the fastener plate.

20. The enclosure of claim 15, wherein the slide bracket includes a curved slot.
